(19) United States
(12) Patent Application Publication
(10) Pub. No.: US 2024/0268076 A1
(43) Pub. Date: Aug. 8, 2024

(54) HEATSINK STRUCTURE AND HEATSINK SYSTEM COMPRISING A PLURALITY OF HEATSINK STRUCTURES

(71) Applicant: Rohde & Schwarz GmbH & Co. KG, Munich (DE)

(72) Inventors: Yin TAN, Singapore (SG); Ah Hock Law, Singapore (SG)

(73) Assignee: Rohde & Schwarz GmbH & Co. KG, Munich (DE)

(21) Appl. No.: 18/164,366

(22) Filed: Feb. 3, 2023

(51) Int. Cl. H05K 7/20

(52) U.S. Cl. CPC H05K 7/20409; H05K 7/20436

(57) ABSTRACT

The present disclosure relates to a heatsink structure, comprising: a base, and a plurality of fins which extend from the base, wherein the base comprises a recess in at least one space between two adjacent fins, and wherein at least one fin comprises a tip that is designed to match the shape of the recess, such that two of the heatsink structures can be joined with each other by interlocking at least one tip of one heatsink structure with at least one recess of the other heatsink structure and vice versa.

### TECHNICAL FIELD

The disclosure relates to a heatsink structure for cooling electrical equipment and to a heatsink system comprising a plurality of such heatsink structures.

### BACKGROUND ART

A heatsink (also: heat sink) is used to transfer heat from an electrical or mechanical device to a surrounding medium, e.g. air, thereby cooling the device. Heatsinks are typically designed to have a large surface area in contact with the surrounding medium.

However, some complex heatsink designs may be difficult to fabricate or require expensive tooling and/or multiple manufacturing processes to manufacture which increases their production costs.

For instance, the document US 2007/0074850 A1 discloses a heat sink assembly comprising a base having a slot with a first and second sidewall and a fin having an end pressed into the slot. The fin end comprises a first surface engaged with the first sidewall of the slot and a second surface with protrusions that are cold-welded to the second sidewall of the slot.

### SUMMARY

Thus, there is a need to provide an improved heatsink structure which avoids the above-mentioned disadvantages.

This is achieved by the embodiments provided in the enclosed independent claims. Advantageous implementations of the present disclosure are further defined in the dependent claims.

According to a first aspect, the present disclosure relates to a heatsink structure, comprising: a base, and a plurality of fins which extend from the base. The base comprises a recess in at least one space between two adjacent fins, wherein at least one fin comprises a tip that is designed to match the shape of the recess, such that two of the heatsink structures can be joined with each other by interlocking at least one tip of one heatsink structure with at least one recess of the other heatsink structure and vice versa.

This achieves the advantage that heat sink structures are provided that can be interconnected in a simple way to generate a heatsink with a more complex design, e.g. with a varying fin density. The individual heatsink structures can, thereby, be fabricated in a simple and low cost way, preferably using only a single tool and process.

The heatsink structure can be mounted to a component of an electrical or mechanical device or equipment. For instance, the heatsink structure is mounted to a PCB (printed circuit board) of an electrical device. As such, the heatsink structure can be part of a cooling system of the device.

For example, the base may comprise a respective recess in the space between each two adjacent fins of the heatsink structure, and/or each fin of the heatsink structure may comprise a tip that is designed to match the shape of each of the recesses.

The base may comprises a base plate. The fins can be arranged to extend from one side of the base plate. The other side of the base plate can be mounted to the device to be cooled.

In an embodiment, the interlocked tips and recesses of two heatsink structures are joined by force fitting. This achieves the advantage that the structures can be joined together in a simple way. Thereby, a good thermal contact can be achieved.

In an embodiment, the interlocked tips and recesses of two heatsink structures are joined by cold welding. This achieves the advantage that the structures can be joined together in a simple way. Thereby, a good thermal contact can be achieved.

In an embodiment, the tip of the at least one fin has a teardrop shape or a nub shape. In particular, the at least one recesses has a complementary shape to such that each tip can be interlocked with a recess (of another structure of the same design).

In an embodiment, the heatsink structure is made from one piece. This achieves the advantage that the heatsink structure can be fabricated in a simple and low cost way, preferably only using a single tool and process.

In an embodiment, the heatsink structure is produced with at least one of the following processes: extrusion, die-casting, blazing, or skiving.

According to a second aspect, the present disclosure relates to a heatsink system comprising a plurality of heatsink structures according to the first aspect of the disclosure. The plurality of heatsink structures can be two or more heatsink structures.

In an embodiment, at least two of the plurality of heatsink structures are connected to each other by their respective bases, wherein the fins of the connected heatsink structures face in different directions. This achieves the advantage that a complex 3D heatsink design can be realized.

For instance, a heatsink system with fins on more than one side, e.g. all four sides, can be formed by joining several heatsink structures (which have fins on only one side) by their respective bases. The bases, e.g. base plates, can be screwed together, wherein thermal grease can be applied between the individual heatsink structures to achieve a good thermal contact.

In an embodiment, at least two of the plurality of heatsink structures are arranged opposite of each other with the fins facing each other.

In an embodiment, at least one fin of each of the two opposite heatsink structures extends into the space between two fins of the other heatsink structure without touching the other heatsink structure.

In an embodiment, the two opposite heatsink structures are joined by interlocking at least one tip of each of the two heatsink structures with at least one recess of the other heatsink structure.

In an embodiment, the interlocked tips and recesses are joined by force fitting. This achieves the advantage that the structures can be joined together in a simple way. Thereby, a good thermal contact can be achieved.

In an embodiment, the interlocked tips and recesses are joined by cold welding. This achieves the advantage that the structures can be joined together in a simple way. Thereby, a good thermal contact can be achieved.

In an embodiment, the two opposite heatsink structures are arranged lengthwise staggered. This achieves the advantage that a larger, elongated heatsink system can be formed from a plurality of heatsink structures.

In an embodiment, the plurality of heatsink structures are arranged in an alternating and partially overlapping manner. This achieves the advantage that a larger, elongated heatsink system can be formed from a plurality of heatsink structures.

In particular, several heatsink structures can be cascaded together to form a larger and more complex heatsink system. Thus, a highly flexibly heatsink concept can be provided based on a plurality of smaller, interconnectable heatsink structures.

The above description with regard to the heatsink structure according to the first aspects of the disclosure is correspondingly valid for the heatsink system according to the second aspect of the disclosure.

### BRIEF DESCRIPTION OF THE DRAWINGS

The above-described aspects and implementation forms of the present disclosure will be explained in the following description of specific embodiments in relation to the enclosed drawings, in which:

FIGS. 1A-1D show schematic diagrams of a heatsink structure according to an embodiment;

FIGS. 2A-2B show schematic diagrams of a heatsink system according to an embodiment;

FIGS. 3A-3C show schematic diagrams of a heatsink system according to an embodiment;

FIGS. 4A-4C show schematic diagrams of a heatsink system according to an embodiment;

FIGS. 5A-5B show schematic diagrams of a heatsink system according to an embodiment;

FIG. 6 shows schematic diagrams of a heatsink system according to an embodiment; and

FIGS. 7A-7B show schematic diagrams of a heatsink system according to an embodiment.

### DETAILED DESCRIPTIONS OF EMBODIMENTS

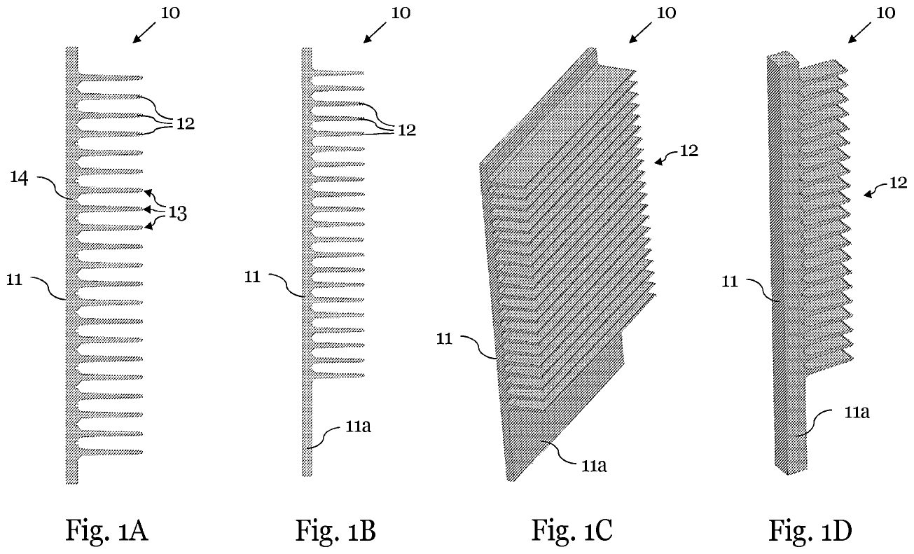

FIGS. 1A-1D show schematic diagrams of a heatsink structure 10 according to an embodiment. Thereby, FIGS. 1A-1B show side-views and FIGS. 1C-1D show perspective views of the heatsink structure 10.

The heatsink structure 10 comprises a base 11 and a plurality of fins 12 which extend from the base 11. The base 11 comprises a recess 14 in at least one space between two adjacent fins 12, wherein at least one fin 12 comprises a tip 13 that is designed to match the shape of the recess 14. In this way, two of the heatsink structures 10 can be joined with each other by interlocking at least one tip 13 of one heatsink structure 10 with at least one recess 14 of the other heatsink structure and vice versa.

In particular, as shown in FIGS. 1A-1D, the base may comprise a respective recess 14 in the spaces between each two adjacent fins 12 of the heatsink structure 10, and each fin 12 of the heatsink structure may comprise a tip 13 that is designed to match the shape of the recesses 14.

The heatsink structure 10 can be used for cooling electrical equipment. Therefore, the heatsink structure 10 can be mounted to a component, e.g. a printed circuit board (PCB), of the electrical equipment by its base 11. For instance, the heatsink structure 10 could be implemented in a measurement instrument (e.g., an oscilloscope or a signal/spectrum analyzer), a power supply, an amplifier or a test and measurement device for broadcasting.

The fins 12 can be plate fins, i.e., elongated, narrow structures that extend along an extension direction that is parallel to the base 11 (as can be seen in FIGS. 1C and 1D). The space between two adjacent fins 12 can form a channel through which a cooling medium, e.g. air, can flow.

The base 11 can be a base plate. The fins 12 can be arranged evenly spaced on the base plate.

As can be seen in FIGS. 1B-1D, the base 11 can comprise a section 11a without fins 12. This section 11a can facilitate the mounting of the heatsink structure 10 to an electrical or mechanical device or equipment.

The tips 13 of the fins can have a teardrop shape or a nub or nipple shape. The recesses 14 between the fins 12 can have a complementary shape to the tips 13 such that each tip 13 can be interlocked with a respective recess 14 (of another heatsink structure 10).

The recesses 14 can be indentations or depressions in the base 11 which can be shaped to accommodate the complementary shaped tips 13.

The heatsink structure 10, in particular the base 11 and the fins 12 of the heatsink structure 10, can be formed from one piece.

In particular, the heatsink structure 10 can be formed from a material with high thermal conductivity, such as copper or aluminum.

For instance, the heatsink structure is fabricated with at least one of the following processes: extrusion, die casting, blazing, or skiving. Preferably, only one of these processes is used to fabricate the heatsink structure 10. This provides the advantage of a simple tool design for fabricating the heatsink structure 10. In particular, only one tool is required for said fabrication. Thus, tool costs for manufacture can be kept low.

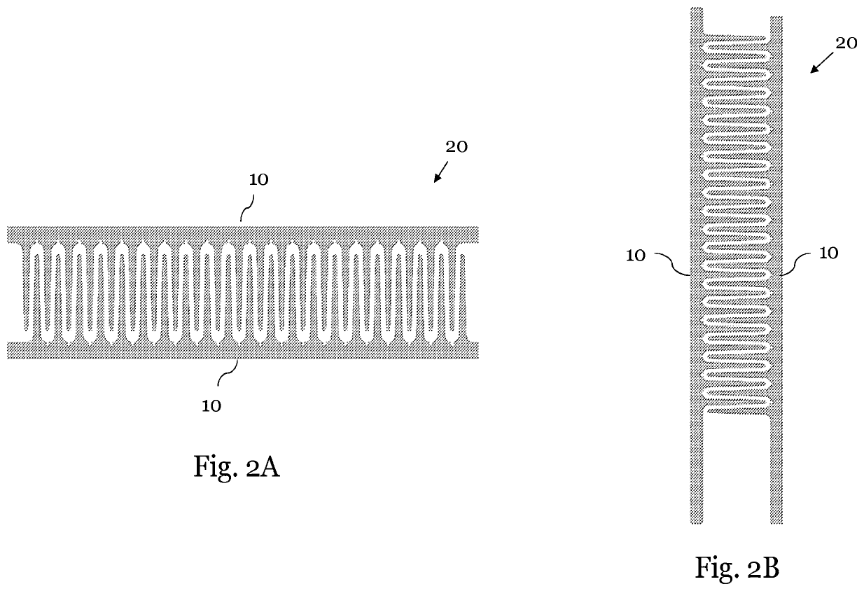

FIGS. 2A-2B show schematic diagrams of a heatsink system 20 according to an embodiment.

The heatsink system 20 comprises two heatsink structures 10 (e.g., structures 10 as shown in FIGS. 1A-1D), wherein the two heatsink structures 10 are arranged opposite of each other with the fins 12 facing each other.

In the exemplary system 30 shown in FIGS. 2A-2B, the fins 12 of each of the two opposite heatsink structures 10 extends into the space between two fins 12 of the other heatsink structure 10 without touching the other heatsink structure, in particular without touching the fins 12 of the other heatsink structure 10.

By combining the heatsink structures 10 in this way, a heatsink with double the fin density of a single structure 10 can be formed. Depending on fin-to-fin gap requirements, both heatsink structures 10 can be spaced apart further or closer.

In the exemplary system 30 shown in FIGS. 2A and 2B, the tips 13 and recesses 14 of the two structures 10 are not interlocked. Instead, both heatsink structures 10 can be secured together by secondary processes and/or by additional parts which are not shown.

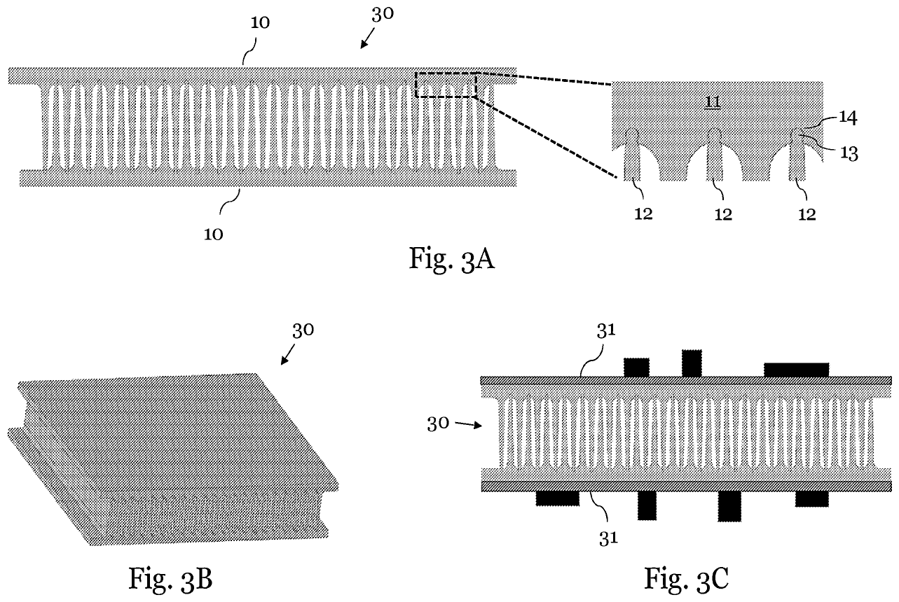

FIGS. 3A-3C show schematic diagrams of a heatsink system 30 according to an embodiment. Thereby, FIGS. 3A and 3C show side views and FIG. 3B shows a perspective view of the heatsink system 30.

The heatsink system 30 in FIGS. 3A-3C comprises two opposite heatsink structures which are joined with each other by interlocking the tips 13 of each of the heatsink structures 10 with the recesses 14 of the other heatsink structure 10.

The interlocked tips 13 and recesses 14 of the two heatsink structures 10 can thereby be joined by force fitting. In particular, the interlocked tips 13 and recesses 14 of two heatsink structures can be joined by cold welding. In this way, a good thermal contact between the structures 10 can be provided.

In particular, the fitting features, e.g. the shape of the tips 13 and the recesses 14, can be a part of the heatsink structure design. In other words, the heatsink structures 10 can be fabricated with matching tips 13 and recesses 14, such that two or more heatsink structures 10 (of the same type) can be interlocked with each other as shown in FIGS. 3A-3C.

Preferably, when the heatsink structures 10 are joined by interlocking their tips 13 and recesses 14, the remaining parts of the heatsink structures 10, e.g. the side surfaces of the fins 12, are not in physical contact. Thus, the surface area of the joined heatsink structures 10 can essentially correspond to the surface area of both individual heatsink structures (minus the interlocked recesses and tips).

Thus, interlocking two heatsink structures 10 in this way can provide a heatsink with increased, in particular doubled, fin density. In particular, the fin-to-fin distance between the interlocking fins 12 of the system 30 can be smaller than the minimum fin-to-fin distance that can be realized in a conventional heatsink that is formed by an extrusion process. Preferably, the design of the individual heatsink structures 10 enables their manufacture with a single tool (e.g., extrusion or die cast).

FIG. 3C shows a heatsink system 30 according to FIGS. 3A and 3B with PCBs 31 mounted to the respective base 11 of both interlocked heatsink structures 10. This heatsink system 30 provides a high fin density (double the fin density of one structure 10) and can be used for cooling components on both PCBs 31.

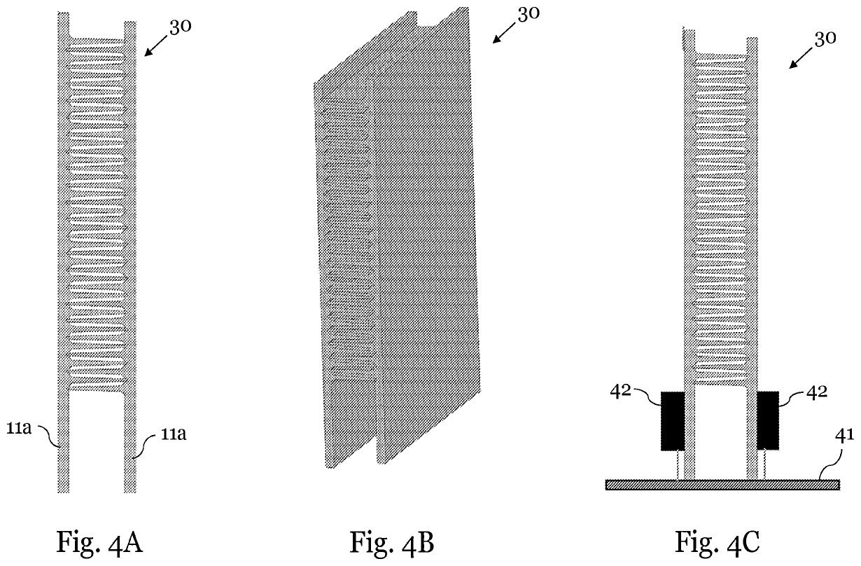

FIGS. 4A-4C show schematic diagrams of a heatsink system 30 according to an embodiment.

In particular, FIGS. 4A-4C show a heatsink system 30 as depicted in FIGS. 3A-3C in a vertical arrangement, wherein the base 11 of each of the joined heatsinks 10 comprises a section 11a without fins 12. As shown in FIG. 4C, this section 11a can be used for mounting the structures 10 to a surface, e.g., to a PCB 41. For example, components on the PCB 41 that give off a lot of heat, e.g. MOSFETs 42, can thereby be coupled directly to said sections 11a.

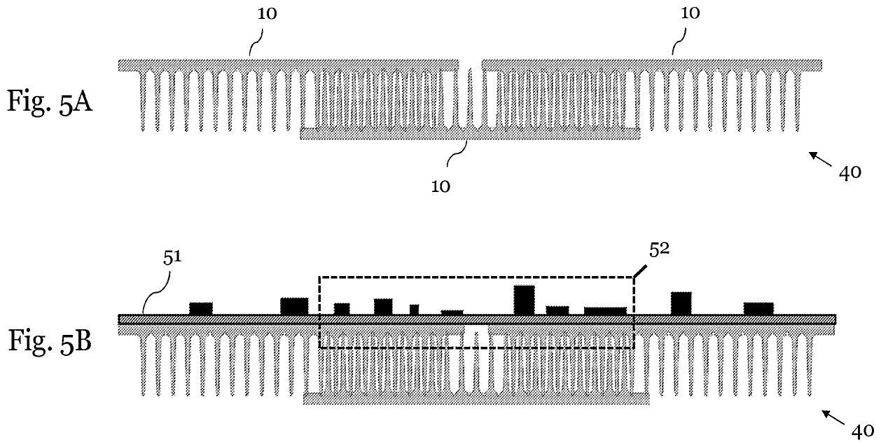

FIGS. 5A-5B show schematic diagrams of a heatsink system 40 according to an embodiment.

The heatsink system 40 shown in the side-views of FIGS. 5A-5B comprises three heatsink structures 10 which are joined by interlocking a portion of the tips 13 of each heatsink structure 10 with a portion of the recesses 14 of another heatsink structure 10 (and vice versa). The heatsink structures 10 are thereby arranged in an alternating (with respect to the opposite sides) and partially overlapping manner, i.e., they are staggered in length and partially overlap.

In the exemplary system 40 shown in FIGS. 5A and 5B, two heatsink structures 10 are arranged on a top side, and a third heatsink structure 10 is arranged on a bottom side, wherein the two structures 10 on the top side are both interlocked with the heatsink structure 10 on the bottom.

In this way, a plurality of heatsink structures 10 can be cascaded together, to achieve a bigger heatsink size and/or to generate a heatsink with a locally increased fin density and, thus, higher surface area in certain sections of the heatsink.

For instance, FIG. 5B shows a PCB 51 being attached to the bases 11 of the top heatsink structures 10. In the highlighted area 52 where the heatsink structures 10 are overlapping, the fin density is increased. This increased fin density increases the heat dissipation capabilities of the heatsink system 40 in this area 52 such that more heat can be removed (dissipated). For example, the heatsink system 40 can be mounted to the PCB 51 such that hot components on the PCB 51 are located at the area 52 of the increased fin density.

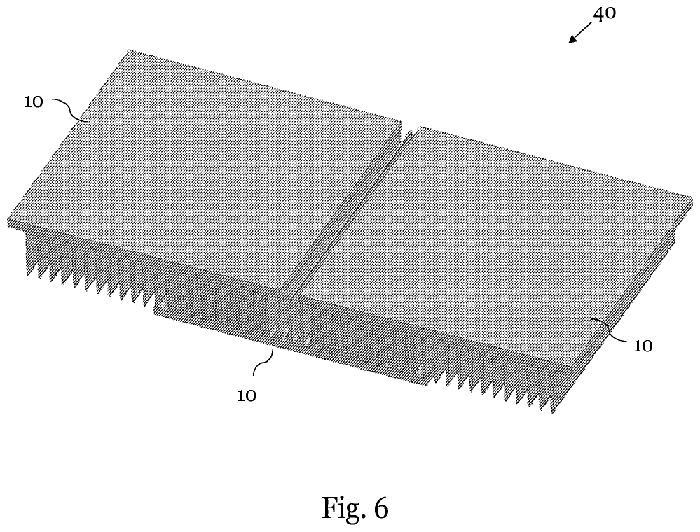

FIG. 6 shows a perspective view of the heatsink system 40 from FIGS. 5A-5B according to an embodiment.

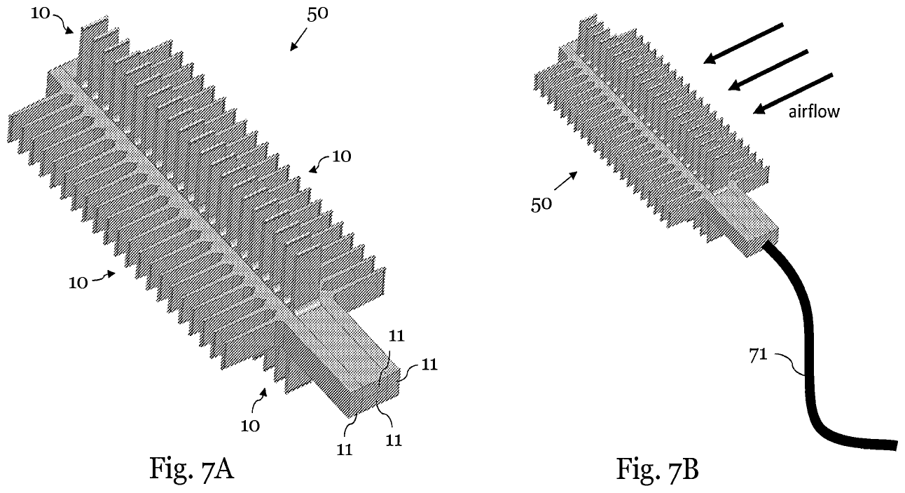

FIGS. 7A-7B show schematic diagrams of a heatsink system 50 according to an embodiment. The heatsink system 50 comprises a plurality of heatsink structures 10 that are connected to each other by their bases 11, wherein the fins 12 of the connected heatsink structures face in different directions.

For instance, FIGS. 7A-7B show an exemplary embodiment of a system 50 comprising four connected heatsink structures 10, wherein the fins 12 of the connected structures face in four different directions. In this way, a heatsink system 50 with a complex 3D shape can be realized.

FIG. 5B shows the heatsink system 50 being connected to a heat pipe 71 and a possible air flow to which the system 50 can transfer the heat. Due to its complex, three-dimensional shape, the heatsink system 50 can provide a large surface area and can provide good cooling performance for different airflow directions.

In particular, the heatsink system 50 can have a shape which cannot be die casted or extruded in a single process step. Thus, by combining individual heatsink structures 10 as shown in FIGS. 7A-7B, complex heatsink designs, which cannot be produced with conventional techniques, can be realized.

For instance, a system 50 as shown in FIGS. 7A-7B can be formed from a plurality of individual heatsink structures 10 via secondary processes. These secondary processes can comprise: fixing the heatsink structures 10 to each other, e.g. via screws or other fastening means, applying thermal grease between the connected heatsink structures 10, and/or milling the connected structures to provide means for connecting the heat pipe 71.

All features described above or features shown in the figures can be combined with each other in any advantageous manner within the scope of the disclosure.

1. A heatsink structure, comprising:
a base, and
a plurality of fins which extend from the base,
wherein the base comprises a recess in at least one space between two adjacent fins, and
wherein at least one fin comprises a tip that is designed to match the shape of the recess, such that two of the heatsink structures can be joined with each other by interlocking at least one tip of one heatsink structure with at least one recess of the other heatsink structure and vice versa.

2. The heatsink structure of claim 1,
wherein the interlocked tips and recesses of two heatsink structures are joined by force fitting.

3. The heatsink structure of claim 1,
wherein the interlocked tips and recesses of two heatsink structures are joined by cold welding.

4. The heatsink structure of claim 1,
wherein the tip of the at least one fin has a teardrop shape or a nub shape.

5. The heatsink structure of claim 1,
wherein the heatsink structure is made from one piece.

6. The heatsink structure of claim 1,
wherein the heatsink structure is produced with at least one of the following processes: extrusion, die casting, blazing, or skiving.

7. A heatsink system comprising a plurality of heatsink structures of claim 1.

8. The heatsink system of claim 7,
wherein at least two of the plurality of heatsink structures are connected to each other by their respective bases,
wherein the fins of the connected heatsink structures face in different directions.

9. The heatsink system of claim 7,
wherein at least two of the plurality of heatsink structures are arranged opposite of each other with the fins facing each other.

10. The heatsink system of claim 9,
wherein at least one fin of each of the two opposite heatsink structures extends into the space between two fins of the other heatsink structure without touching the other heatsink structure.

11. The heatsink system of claim 9,
wherein the two opposite heatsink structures are joined by interlocking at least one tip of each of the two heatsink structures with at least one recess of the other heatsink structure.

12. The heatsink system of claim 11,
wherein the interlocked tips and recesses are joined by force fitting.

13. The heatsink system of claim 11,
wherein the interlocked tips and recesses are joined by cold welding.

14. The heatsink system of claim 9,
wherein the two opposite heatsink structures are arranged lengthwise staggered.

15. The heatsink system of claim 9,
wherein the plurality of heatsink structures are arranged in an alternating and partially overlapping manner.
